(19) United States
(12) Patent Application Publication
(10) Pub. No.: US 2025/0079571 A1
(43) Pub. Date: Mar. 6, 2025

(54) THERMAL MANAGEMENT MODULE

(71) Applicant: C-TECH UNITED CORPORATION, New Taipei City (TW)

(72) Inventors: CHIH-KUN YANG, New Taipei City (TW); YU-CHUN WANG, New Taipei City (TW); JUI-YANG CHANG, New Taipei City (TW)

(21) Appl. No.: 18/457,359

(22) Filed: Aug. 29, 2023

(51) Int. Cl. H01M 10/657; H01L 23/467; H01L 25/18; H01M 10/42; H01M 10/613; H01M 10/6563; H10N 39/00

(52) U.S. Cl. CPC H01M 10/657; H01L 23/467; H01L 25/18; H01M 10/425; H01M 10/613; H01M 10/6563; H10N 39/00; H01M 2010/4271

(57) ABSTRACT

A thermal management module includes a substrate, a computing unit, a heat dissipation block, and at least one piezoelectric cooling unit. The computing unit is disposed on the substrate. A heating part of the computing unit is covered by the heat dissipation block, and the heat dissipation block can absorb heat energy generated by the computing unit. The piezoelectric cooling unit includes a piezoelectric actuator module and a heat dissipation sheet. The piezoelectric actuator module is disposed on the substrate. The piezoelectric actuator module is electrically coupled to an alternating voltage, and can generate a mechanical vibration. A fixed end of the heat dissipation sheet is fixed on the piezoelectric actuator module. When the piezoelectric actuator module generates the mechanical vibration, the free end can swing and create an airflow that passes through the heat dissipation block.

### FIELD OF THE DISCLOSURE

The present disclosure relates to a thermal management module, and more particularly to a thermal management module for a plurality of batteries.

### BACKGROUND OF THE DISCLOSURE

Battery devices on the market typically include a shell, and a battery pack and a battery management structure that are disposed in the shell. The shell often has a plurality of cooling holes. Accordingly, heat generated by the battery management structure can be dissipated through an ambient airflow, so as to avoid affecting operation of the battery management structure (e.g., a lifespan of the battery management structure is reduced, and efficiency of the battery management structure is low). However, if the battery devices only rely on the ambient airflow to achieve passive heat dissipation and temperature uniformity, the effects are limited. As such, designers will also install cooling fans inside the shell.

Although the cooling fans can actively achieve effective heat dissipation and temperature uniformity, the motors of the cooling fans are based on bulky structures such as stators and rotors, so that the battery devices are difficult to miniaturize (especially waterproof battery devices).

### SUMMARY OF THE DISCLOSURE

In response to the above-referenced technical inadequacy, the present disclosure provides a thermal management module.

In order to solve the above-mentioned problem, one of the technical aspects adopted by the present disclosure is to provide a thermal management module used to manage a battery pack. The thermal management module includes a substrate, a computing unit, a heat dissipation block, and at least one piezoelectric cooling unit. The computing unit is disposed on the substrate. The computing unit can collect information of the battery pack for calculation and management. A heating part of the computing unit is covered by the heat dissipation block, and the heat dissipation block is configured to absorb a heat energy generated by the computing unit during operation through the heating part. The at least one piezoelectric cooling unit is disposed on one side of the heat dissipation block. The at least one piezoelectric cooling unit includes a piezoelectric actuator module and a heat dissipation sheet. The piezoelectric actuator module is disposed on the substrate. The piezoelectric actuator module is electrically coupled to an alternating voltage and capable of generating a mechanical vibration. The heat dissipation sheet has a fixed end and a free end. The fixed end is fixed on the piezoelectric actuator module. When the piezoelectric actuator module generates the mechanical vibration, the free end is configured to swing and create an airflow that passes through the heat dissipation block.

In one of the possible or preferred embodiments, the heat dissipation block includes a carrier and a plurality of regulating plates that are disposed on a surface of the carrier. A heat dissipation channel is formed between any two adjacent ones of the regulating plates, and the heat dissipation channel is parallel to a longitudinal direction of the heat dissipation sheet for the airflow to pass through.

In one of the possible or preferred embodiments, the at least one piezoelectric cooling unit and the heat dissipation block have a shortest distance there-between and parallel to the longitudinal direction, and the shortest distance is less than or equal to a length of the heat dissipation sheet.

In one of the possible or preferred embodiments, a height of the at least one piezoelectric cooling unit relative to the substrate is greater than or equal to a height of the carrier relative to the substrate.

In one of the possible or preferred embodiments, a quantity of the at least one piezoelectric cooling unit is more than one, the piezoelectric cooling units have a shortest distance there-between, and the shortest distance is greater than or equal to 1.5 times a width of the heat dissipation sheet.

In one of the possible or preferred embodiments, the thermal management module further includes a start module electrically coupled to the piezoelectric actuator module. When the start module detects that a temperature of the heat dissipation block exceeds a predetermined threshold, the start module inputs the alternating voltage to the piezoelectric actuator module, so that the piezoelectric actuator module generates the mechanical vibration.

In one of the possible or preferred embodiments, the computing unit is covered by the heat dissipation block, and an outer surface of the heat dissipation block is a flat structure.

In one of the possible or preferred embodiments, the piezoelectric actuator module of each of the piezoelectric cooling units includes a piezoelectric ceramic piece and two metal plates, and the two metal plates clamp the piezoelectric ceramic piece, so that a plurality of charges on a surface of the piezoelectric ceramic piece are unbalanced.

In one of the possible or preferred embodiments, the heat dissipation sheet of each of the piezoelectric cooling units is further defined as a rectangular sheet that is elastic, the fixed end is clamped by the two metal plates, and the fixed end is configured to absorb an energy of the mechanical vibration through the two metal plates to transfer to the free end.

In one of the possible or preferred embodiments, the two metal plates are further defined as two rectangular sheets, the two metal plates are fixed to each other to be formed as a single one-piece structure, and the heat dissipation sheet is further defined as the two metal plates.

Therefore, in the thermal management module provided by the present disclosure, by virtue of “a heating part of the computing unit being covered by the heat dissipation block, and the heat dissipation block being configured to absorb heat energy generated by the computing unit during operation through the heating part” and “the free end being configured to swing and create an airflow that passes through the heat dissipation block when the piezoelectric actuator module generates the mechanical vibration,” the thermal management module can actively dissipate heat (so as to achieve the purpose of heat dissipation and temperature uniformity), and a battery device using the thermal management module can also be miniaturized.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic planar view of a thermal management module according to a first embodiment of the present disclosure;

FIG. 2 is a schematic cross-sectional view taken along line II-II of FIG. 1;

FIG. 3 is a schematic enlarged view of part III of FIG. 2;

FIG. 4 is a schematic perspective view of a piezoelectric cooling unit according to the first embodiment of the present disclosure;

FIG. 5 is a schematic planar view of another configuration of the thermal management module according to the first embodiment of the present disclosure;

FIG. 6 is a schematic planar view of yet another configuration of the thermal management module according to the first embodiment of the present disclosure;

FIG. 7 is a schematic perspective view of a battery device according to a second embodiment of the present disclosure;

FIG. 8 is a schematic enlarged view of part VIII of FIG. 7;

FIG. 9 is a schematic perspective view of the piezoelectric cooling unit according to the second embodiment of the present disclosure; and

FIG. 10 is a partial schematic enlarged view of another configuration of the battery device according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

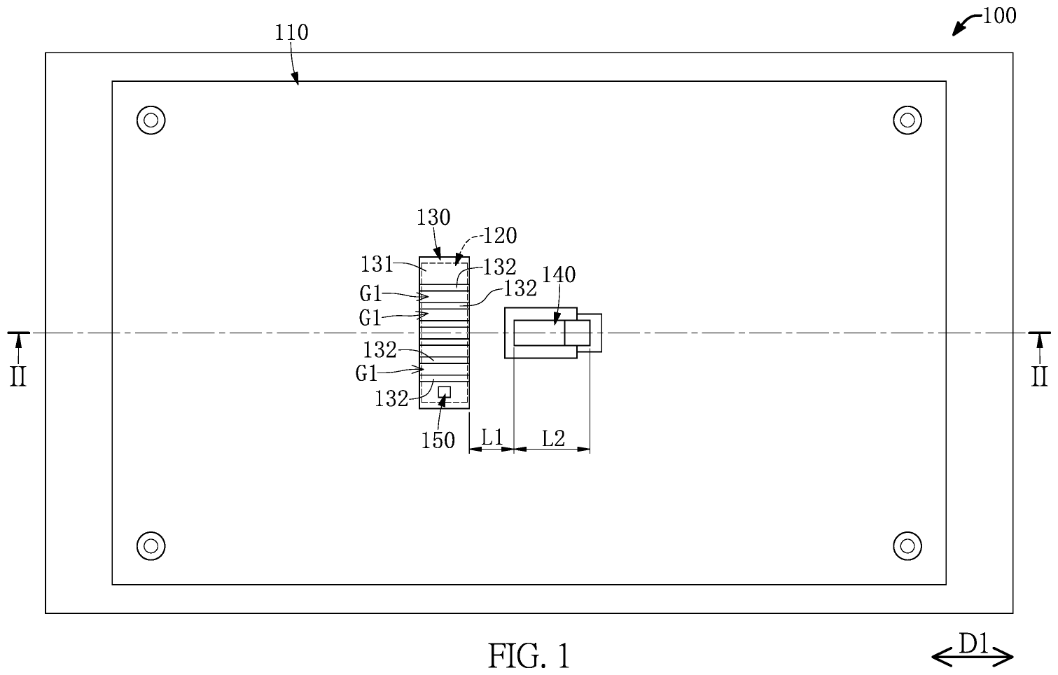

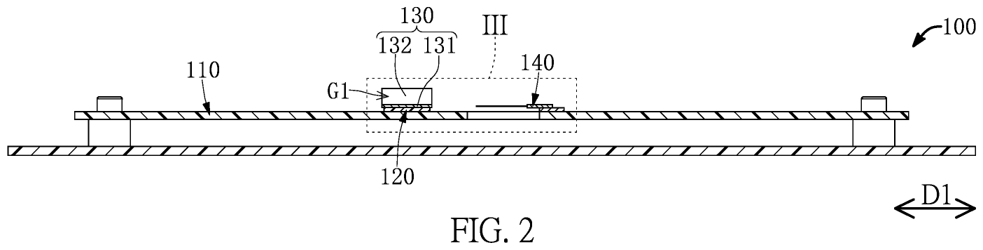

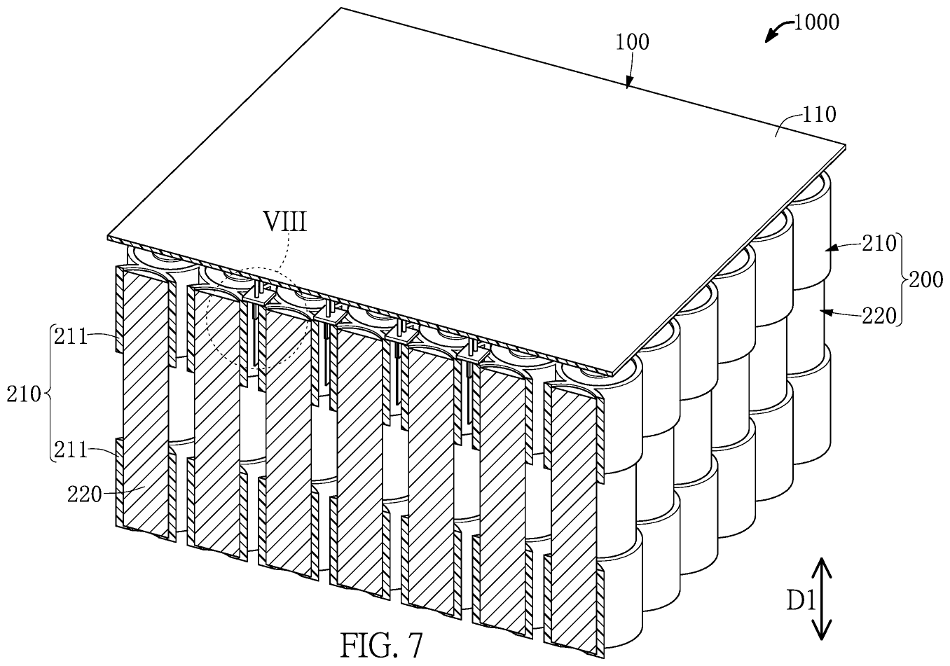

Referring to FIG. 1 to FIG. 6, a first embodiment of the present disclosure provides a thermal management module 100, and the thermal management module 100 can be used to manage a battery pack 200 (as shown in FIG. 7). In other words, the thermal management module 100 of the present disclosure is a part of a battery management system (BMS). As such, any thermal management module that is not applied to the battery management system is not the thermal management module 100 of the present disclosure.

Referring to FIG. 1 to FIG. 3, the thermal management module 100 includes a substrate 110, a computing unit 120 disposed on the substrate 110, a heat dissipation block 130 disposed on the computing unit 120, and at least one piezoelectric cooling unit 140 disposed on one side of the heat dissipation block 130. The following description describes the structure and connection relationships of each component of the thermal management module 100.

Referring to FIG. 1 to FIG. 3, the substrate 110 in the present embodiment is a printed circuit board (PCB), and the substrate 110 can be used to carry various electronic components (e.g., a wireless chip and a memory).

The computing unit 120 is installed on the substrate 110, and the computing unit 120 can collect information of the battery pack 200 (e.g., a voltage, a current, and a temperature of a battery core) for calculation and management. In other words, the computing unit 120 is an electronic component capable of computing, such as a microcontroller unit (MCU).

A heating part of the computing unit 120 is covered by the heat dissipation block 130, and the heat dissipation block 130 can absorb the heat energy generated by the computing unit 120 during operation through the heating part. Specifically, the heat dissipation block 130 in the present embodiment is a heat-conducting metal, and the heat dissipation block 130 includes a carrier 131 and a plurality of regulating plates 132. The carrier 131 has a heat-absorbing surface and a heat-dissipating surface that are opposite to each other, the heat-absorbing surface faces the computing unit 120 to contact the heating part, and the heat-dissipating surface faces away from the substrate 110 for placement of the regulating plates 132. The regulating plates 132 are spaced apart from each other, and a heat dissipation channel G1 is formed between any two adjacent ones of the regulating plates 132.

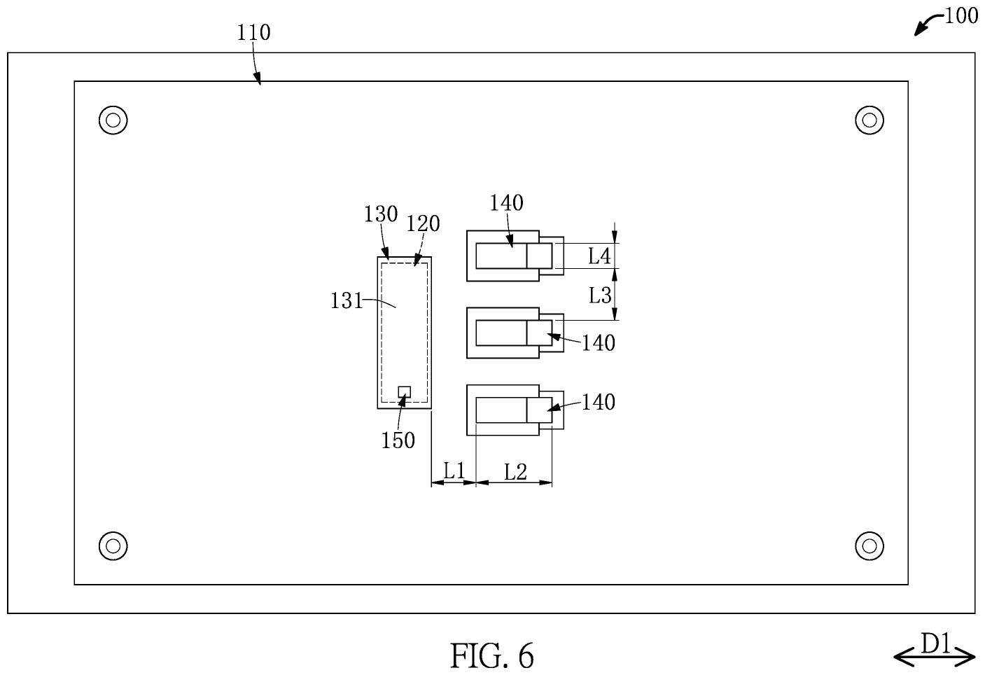

Naturally, the structure of the heat dissipation block 130 is not limited thereto. For example, as shown in FIG. 6, an outer edge of the computing unit 120 may also be covered by the heat dissipation block 130, and an outer surface of the heat dissipation block 130 is a flat structure that serves as the heat-dissipating surface. That is to say, the regulating plates 132 of the heat dissipation block 130 are omitted.

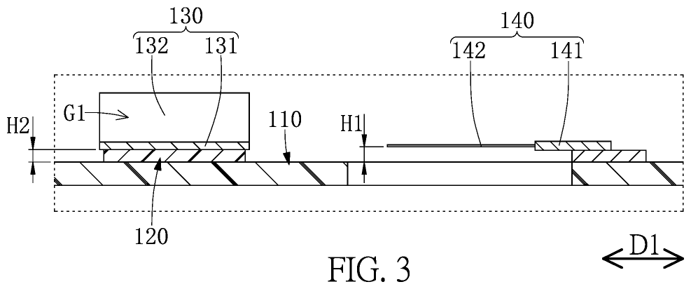

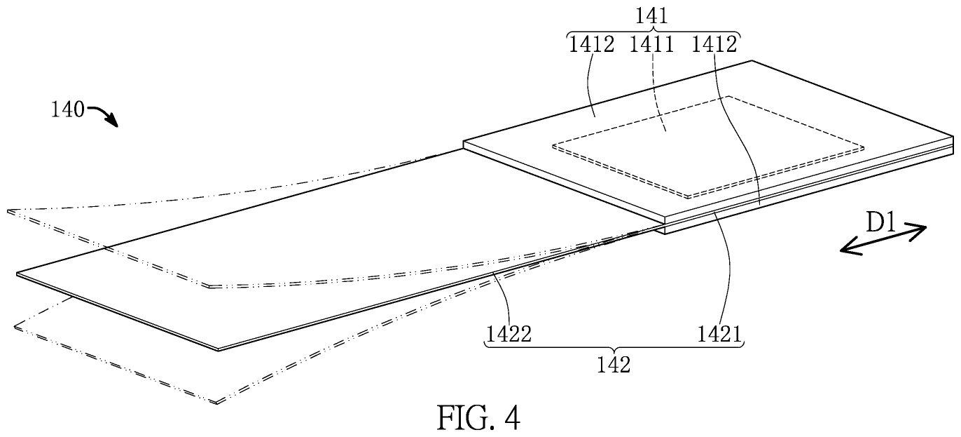

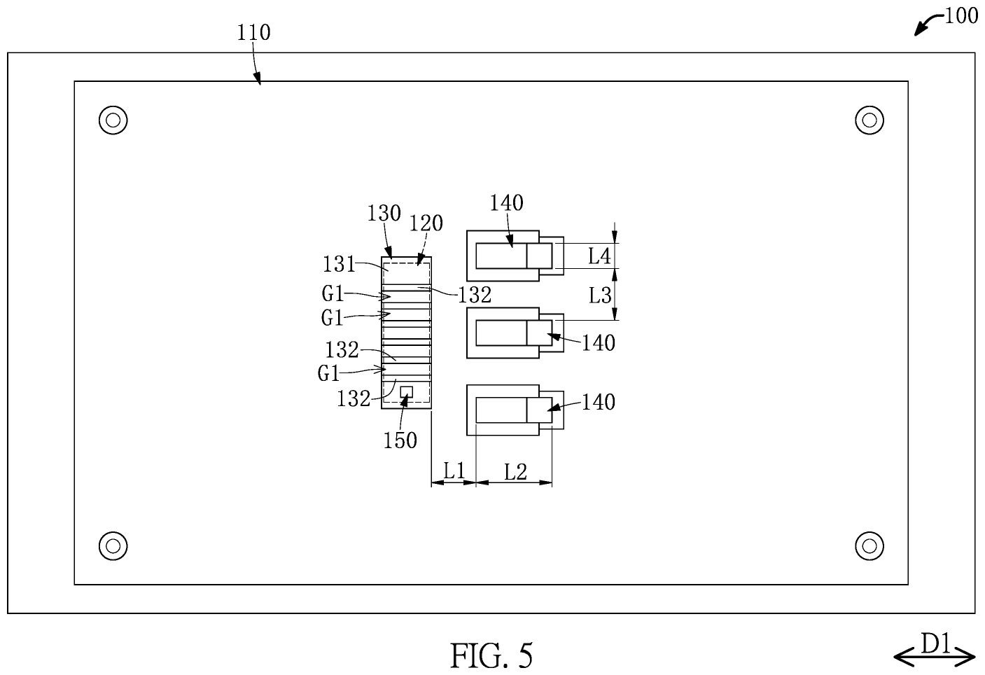

Referring to FIG. 3 and FIG. 4, the at least one piezoelectric cooling unit 140 is disposed on one side of the heat dissipation block 130, and the at least one piezoelectric cooling unit 140 generates an airflow toward the heat dissipation block 130 for heat dissipation and temperature uniformity. It should be noted that, in practice, the quantity of the at least one piezoelectric cooling unit 140 can be one or more (as shown in FIG. 1 and FIG. 5). In the following description, the quantity of the at least one piezoelectric cooling unit 140 is exemplified as being one.

Specifically, the piezoelectric cooling unit 140 includes a piezoelectric actuator module 141 and a heat dissipation sheet 142. The piezoelectric actuator module 141 is disposed on the substrate 110, and the piezoelectric actuator module 141 has a piezoelectric ceramic piece 1411 (e.g., lead zirconate titanate) and two metal plates 1412. The piezoelectric ceramic piece 1411 is clamped by the two metal plates 1412, so that a plurality of charges on a surface of the piezoelectric ceramic piece 1411 are unbalanced. In addition, the two metal plates 1412 respectively generate a positively charged electrode and a negatively charged electrode. Accordingly, when the piezoelectric actuator module 141 is electrically coupled to an alternating voltage (i.e., an electric field is applied to the piezoelectric actuator module 141), the two metal plates 1412 can produce an inverse piezoelectric effect that results in elongation or compression of surfaces of the two metal plates 1412, thereby causing a mechanical vibration.

The heat dissipation sheet 142 in the present embodiment is an elastic rectangular sheet and has a longitudinal direction D1. Moreover, the heat dissipation sheet 142 has a fixed end 1421 and a free end 1422 along the longitudinal direction D1. The fixed end 1421 is fixed on the piezoelectric actuator module 141 (e.g., the fixed end 1421 is clamped by the two metal plates 1412), and the fixed end 1421 can absorb energy of the mechanical vibration, so as to transfer the energy to the free end 1422. In other words, when the piezoelectric actuator module 141 generates the mechanical vibration, the free end 1422 can swing and generate the airflow passing through the heat dissipation block 130.

Preferably, in order to ensure that the airflow generated by the heat dissipation sheet 142 (i.e., the piezoelectric cooling unit 140) can effectively absorb the heat energy from the heat dissipation block 130, the heat dissipation channel G1 is designed to be parallel to the longitudinal direction D1 of the heat dissipation sheet 142 for the airflow to pass through. In addition, the piezoelectric cooling unit 140 and the heat dissipation block 130 have a shortest distance L1 there-between, and the shortest distance L1 is parallel to the longitudinal direction D1 (as shown in FIG. 1). The shortest distance L1 is preferably less than or equal to a length L2 of the heat dissipation sheet 142, so as to prevent the airflow in contact with the heat dissipation block 130 from being too weak (which may affect the cooling effect).

Reference is made to FIG. 5 and FIG. 6. It should be noted that, when the quantity of the at least one piezoelectric cooling unit 140 is more than one, in order to prevent a turbulent airflow caused by any one of the heat dissipation sheets 142 from affecting the airflow generated by other heat dissipation sheets or reducing the cooling efficiency, a height H1 of each of the piezoelectric cooling units 140 relative to the substrate 110 is preferably greater than or equal to a height H2 of the carrier 131 relative to the substrate 110 (as shown in FIG. 3). In this way, it can be ensured that the airflow is not blocked by the carrier 131, thereby preventing generation of a reverse airflow (or the turbulent airflow). In addition, the piezoelectric cooling units 140 have a shortest distance L3 there-between, and the shortest distance L3 is preferably greater than or equal to 1.5 times a width L4 of the heat dissipation sheet 142, so as to prevent the heat dissipation sheets 142 from influencing each other in terms of the heat dissipation effect. For example, due to asynchronous swing directions of the heat dissipation sheets 142, flow velocities of the airflows generated by the heat dissipation sheets 142 may be mutually restrained.

In a practical application, the thermal management module 100 may further include a start module 150 electrically coupled to the piezoelectric actuator module 141. Accordingly, the start module 150 can drive the piezoelectric cooling unit 140 to start according to a temperature of the computing unit 120. More specifically, the start module 150 may include a temperature sensor and a switch. When (the temperature sensor of) the start module 150 detects that a temperature of the heat dissipation block 130 exceeds a predetermined threshold, (the switch of) the start module 150 inputs the alternating voltage to the piezoelectric actuator module 141, so that the piezoelectric actuator module 141 generates the mechanical vibration.

### Second Embodiment

Referring to FIG. 7 to FIG. 10, a second embodiment of the present disclosure provides a battery device 1000. The present embodiment adopts the at least one piezoelectric cooling unit 140 of the thermal management module 100 in the first embodiment. Therefore, the second embodiment shares the same inventive concept as the first embodiment, and the similarities between the at least one piezoelectric cooling unit 140 in the first embodiment and that in the second embodiment will not be reiterated herein. The following description describes the structure and connection relationships of each component of the battery device 1000.

Referring to FIG. 7 to FIG. 9, the battery device 1000 includes a battery pack 200, a substrate 110 installed on one side of the battery pack 200, a computing unit 120 installed on the substrate 110, and a plurality of piezoelectric cooling units 140′ that are installed on the battery pack 200.

The battery pack 200 includes a fixing seat 210 and a plurality of batteries 220. The fixing seat 210 in the present embodiment is made of an insulating material with heat conduction properties (e.g., a heat conduction plastic), and the fixing seat 210 includes a plurality of accommodating grooves 211. Each of the accommodating grooves 211 is a circular tubular structure, and the accommodating grooves 211 are adjacent to each other, so that a heat dissipation channel G2 is formed between any two adjacent ones of the accommodating grooves 211. The batteries 220 are respectively accommodated in the accommodating grooves 211, and surfaces of the batteries 220 can respectively contact (or abut against) inner edges of the accommodating grooves 211, so that waste heat of each of the batteries 220 can be conducted into the heat dissipation channel G2 through the accommodating grooves 211.

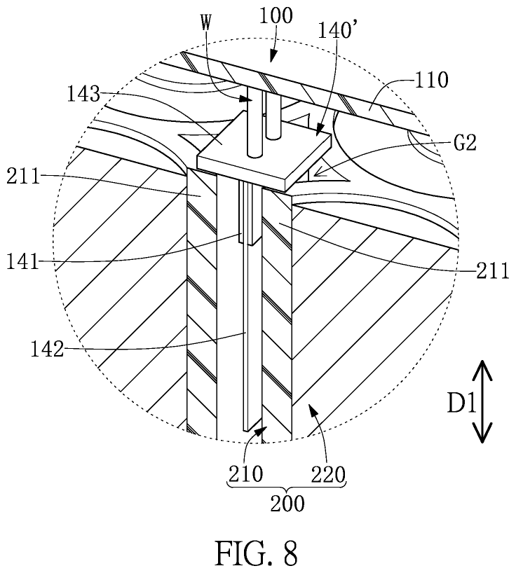

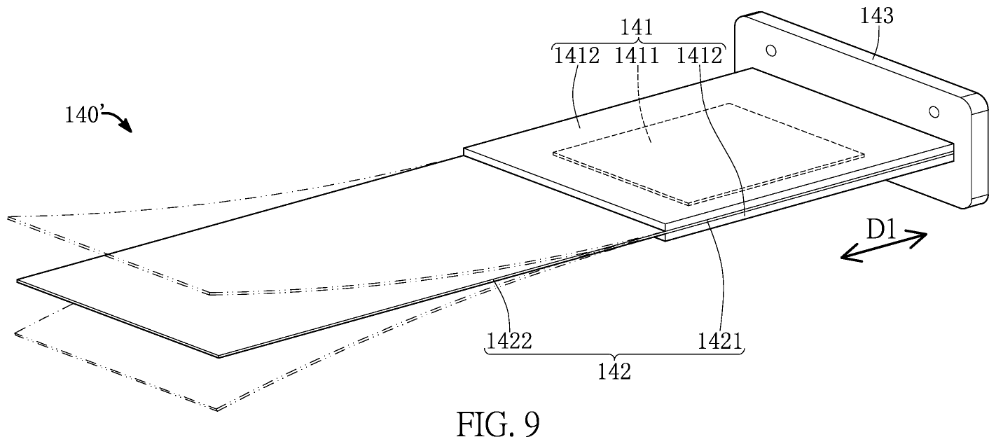

Referring to FIG. 8 and FIG. 9, the structure of each of the piezoelectric cooling units 140′ is substantially the same as that of the piezoelectric cooling unit 140 in the first embodiment. The difference between the present embodiment and the first embodiment mainly resides in that each of the piezoelectric cooling units 140′ in the present embodiment further includes a bottom seat 143. Each of the bottom seats 143 is fixed on end edges of the adjacent accommodating grooves 211, and corresponds in position to the heat dissipation channel G2. In a practical application, the bottom seat 143 can be a sheet-shaped structure, and an area of a width side surface of the bottom seat 143 is greater than a cross-sectional area of the heat dissipation channel G2, so that the bottom seat 143 can abut against an outer edge of the heat dissipation channel G2.

In addition, each of the bottom seats 143 can be fixed on the piezoelectric actuator module 141, so that the piezoelectric actuator module 141 and the heat dissipation sheet 142 that are installed on the piezoelectric actuator module 141 are located in the heat dissipation channel G2. That is to say, the longitudinal direction D1 of the heat dissipation sheet 142 may be parallel to the heat dissipation channel G2 (as shown in FIG. 8).

Accordingly, when the piezoelectric actuator module 141 generates the mechanical vibration, the free end 1422 can swing and generate an airflow passing through the heat dissipation channel G2, so as to discharge the waste heat of each of the batteries 220.

In practice, the computing unit 120 can collect information of the batteries 220 for calculation and management. Therefore, the piezoelectric cooling units 140′ can each be electrically coupled to the computing unit 120 on the substrate 110 through a wire W, so that the piezoelectric cooling units 140′ can be turned on or off by the computing unit 120 according to a temperature of each of the batteries 220.

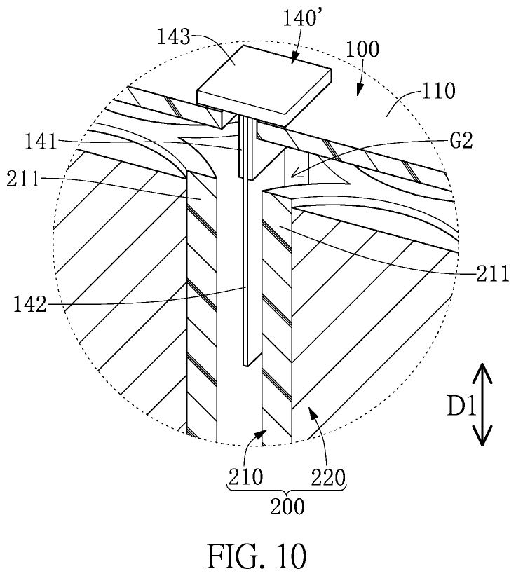

It is worth mentioning that in another configuration (as shown in FIG. 10), the bottom seats 143 of the piezoelectric cooling units 140′ can also be directly fixed on the substrate 110. Furthermore, the bottom seats 143 respectively correspond in position to the heat dissipation channels G2, so that the heat dissipation sheet 142 installed on each of the piezoelectric actuator modules 141 may be located in the heat dissipation channel G2. Accordingly, each of the piezoelectric actuator modules 141 can be without the wire W, and be directly connected to the computing unit 120 through a line on the substrate 110 by welding.

In addition, it should be noted that the substrate 110 and the computing unit 120 of the battery device 1000 are used for battery management. Hence, in another embodiment of the present disclosure (not shown), the substrate 110 and the computing unit 120 can be omitted as appropriate.

### Beneficial Effects of the Embodiments

In conclusion, in the thermal management module provided by the present disclosure, by virtue of “a heating part of the computing unit being covered by the heat dissipation block, and the heat dissipation block being configured to absorb heat energy generated by the computing unit during operation through the heating part” and “the free end being configured to swing and create an airflow that passes through the heat dissipation block when the piezoelectric actuator module generates the mechanical vibration,” the thermal management module can actively dissipate heat (so as to achieve the purpose of heat dissipation and temperature uniformity), and a battery device using the thermal management module can also be miniaturized.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A thermal management module, which is used to manage a battery pack, the thermal management module comprising:
a substrate;
a computing unit disposed on the substrate, wherein the computing unit is configured to collect information of the battery pack for calculation and management;
a heat dissipation block, wherein a heating part of the computing unit is covered by the heat dissipation block, and the heat dissipation block is configured to absorb heat energy generated by the computing unit during operation through the heating part; and
at least one piezoelectric cooling unit disposed on one side of the heat dissipation block, wherein the at least one piezoelectric cooling unit includes:
a piezoelectric actuator module disposed on the substrate, wherein the piezoelectric actuator module is electrically coupled to an alternating voltage and capable of generating a mechanical vibration; and
a heat dissipation sheet having a fixed end and a free end, wherein the fixed end is fixed on the piezoelectric actuator module, and wherein, when the piezoelectric actuator module generates the mechanical vibration, the free end is configured to swing and create an airflow that passes through the heat dissipation block.

2. The thermal management module according to claim 1, wherein the heat dissipation block includes a carrier and a plurality of regulating plates that are disposed on a surface of the carrier, wherein a heat dissipation channel is formed between any two adjacent ones of the regulating plates, and the heat dissipation channel is parallel to a longitudinal direction of the heat dissipation sheet for the airflow to pass through.

3. The thermal management module according to claim 2, wherein the at least one piezoelectric cooling unit and the heat dissipation block have a shortest distance there-between, the shortest distance is parallel to the longitudinal direction, and the shortest distance is less than or equal to a length of the heat dissipation sheet.

4. The thermal management module according to claim 2, wherein a height of the at least one piezoelectric cooling unit relative to the substrate is greater than or equal to a height of the carrier relative to the substrate.

5. The thermal management module according to claim 1, wherein a quantity of the at least one piezoelectric cooling unit is more than one, the piezoelectric cooling units have a shortest distance there-between, and the shortest distance is greater than or equal to 1.5 times a width of the heat dissipation sheet.

6. The thermal management module according to claim 1, further comprising a start module electrically coupled to the piezoelectric actuator module, wherein, when the start module detects that a temperature of the heat dissipation block exceeds a predetermined threshold, the start module inputs the alternating voltage to the piezoelectric actuator module, so that the piezoelectric actuator module generates the mechanical vibration.

7. The thermal management module according to claim 1, wherein the computing unit is covered by the heat dissipation block, and an outer surface of the heat dissipation block is a flat structure.

8. The thermal management module according to claim 1, wherein the piezoelectric actuator module of the at least one piezoelectric cooling unit includes a piezoelectric ceramic piece and two metal plates, and the two metal plates clamp the piezoelectric ceramic piece, so that a plurality of charges on a surface of the piezoelectric ceramic piece are unbalanced.

9. The thermal management module according to claim 8, wherein the heat dissipation sheet of the at least one piezoelectric cooling unit is further defined as an elastic rectangular sheet, the fixed end is clamped by the two metal plates, and the fixed end is configured to absorb energy of the mechanical vibration through the two metal plates, so as to transfer the energy to the free end.

10. The thermal management module according to claim 8, wherein the two metal plates are further defined as two rectangular sheets, the two metal plates are fixed to each other to form a single one-piece structure, and the heat dissipation sheet is further defined as the two metal plates.
